(19) United States
(12) Patent Application Publication
(10) Pub. No.: US 2014/0091417 A1
(43) Pub. Date: Apr. 3, 2014

(54) LOW REFRACTIVE INDEX COATING DEPOSITED BY REMOTE PLASMA CVD

(71) Applicant: Applied Materials, Inc., Santa Clara, CA (US)

(72) Inventors: Sum-Yee Betty TANG, Cupertino, CA (US); Martin SEAMONS, San Jose, CA (US); Kiran V. THADANI, Sunnyvale, CA (US); Abhijit MALLICK, Fremont, CA (US)

(73) Assignee: Applied Materials, Inc., Santa Clara, CA (US)

(21) Appl. No.: 14/040,624

(22) Filed: Sep. 28, 2013

Related U.S. Application Data
(60) Provisional application No. 61/708,613, filed on Oct. 1, 2012.

(51) Int. Cl. C09D 5/00; H01L 31/18; H01L 31/0232

(52) U.S. Cl. CPC C09D 5/006; H01L 31/02325; H01L 31/18
USPC 257/432; 106/287.28; 257/431; 438/69

(57) ABSTRACT

A method of depositing a low refractive index coating on a photo-active feature on a substrate comprises forming a substrate having one or more photo-active features thereon and placing the substrate in a process zone. A deposition gas is energized in a remote gas energizer, the deposition gas comprising a fluorocarbon gas and an additive gas. The remotely energized deposition gas is flowed into the process zone to deposit a low refractive index coating on the substrate.

### CROSS-REFERENCE

The present application claims priority to U.S. Provisional Application 61/708,613, filed on Oct. 1, 2012, which is incorporated by reference and in its entirety.

### BACKGROUND

Embodiments of the present invention relate to low refractive index coatings, their applications, and methods of fabrication.

Low refractive index (LIR) coatings have been used, for example, as anti-reflective (AR) coatings for coating photo-active features of a photo-active device to reduce glare and surface reflectance and as polarizing films. LIR increase the transmission of visible light through the photo-active device by reducing surface/interface reflectance losses and by eliminating stray light. Such coatings can be applied to an image sensor such as a photodetector, optical interconnect, camera, vision and guidance system, navigation system, automotive system, and other consumer products. For example, LIR coatings are applied on microelectronic image sensors such as Complementary Metal-Oxide Semiconductor (CMOS) systems, Charged Coupled Device (CCD) arrays, and other solid-state imaging systems. In CCD arrays, pixels are represented by p-doped MOSFET capacitors, and such sensors are often used in digital cameras. CMOS image sensors are active pixel sensors made by CMOS semiconductor processes and as such, can have lower fabrication costs than CCD arrays. In a CMOS image sensor, each photo sensor converts light energy to a voltage signal, and optionally converts the voltage signal to digital data or otherwise processes the image or voltage signal to generate a processed output signal. Active pixel sensors have transistors within each pixel cell, and can be arranged as a pixel array with columns. LIR coatings can also be applied to displays such as liquid crystal displays, plasma television displays, PC monitors, portable computer screens, PDAs, electronic game displays, scoreboards and marquis.

The efficiency of a low refractive index coating is often determined by the value of its refractive index. For example, a LIR coating can be used to coat a lens of a complementary metal oxide semiconductor (CMOS) image sensor to reduce reflectance and increase the light transmittance and image quality of the sensor. Typically, such LIR coatings fabricated by depositing a silicon dioxide film having a refractive index of 1.46 which only reduces surface reflectivity from 5% to about 3%. LIR coatings having still lower refractive indices are often difficult to achieve with conventional silicon dioxide films at temperatures below 200° C. as required for many CMOS sensor devices. LIR coatings can also include a series of sequentially deposited high refractive index and low refractive index films. However, the efficiency of such multi-layer low refractive index coatings can be limited by the value of the low refractive index film component. LIR coatings having a low refractive index of less than 1.4, such as Teflon®-type coatings, have been fabricated using conventional wet-processing methods such as spin coating. However in spin coating, after a liquid polymer precursor is spun in the liquid state to form a coating, the coating is baked at temperatures exceeding 400° C. which causes thermal degradation of the underlying imaging or display device. Also, spin coating is used to deposit only planarized films, while conformal deposition on non-planar surfaces is often required for AR coating over imaging features like microlenses.

For various reasons that include these and other deficiencies, and despite the development of coatings having low refractive indices and their deposition methods, further improvements in such coatings are continuously being sought.

### SUMMARY

A method of depositing a low refractive index coating on a photo-active feature on a substrate comprises forming a substrate having a plurality of photo-active features thereon and placing the substrate in a process zone of a process chamber. The process chamber is coupled to a remote gas energizer which is at a distance from and outside the process chamber. A deposition gas is flowed through the remote gas energizer, the deposition gas comprising a fluorocarbon gas and an additive gas. The deposition gas is energized by inductively coupling RF energy to the deposition gas while the deposition gas travels through the remote gas energizer. The remotely energized deposition gas is flowed into the process zone to deposit the low refractive index coating on the substrate.

A low refractive index coating comprises an amorphous structure containing carbon and fluorine, CF2 bonds present in an atomic percentage of at least about 60%, and a refractive index of less than about 1.33.

A coated photo-active device comprises a photo-active feature a low refractive index coating overlying the photo-active feature, the low refractive index coating comprising an amorphous structure containing carbon and fluorine, CF2 bonds present in an atomic percentage of at least about 60%, and a refractive index of less than about 1.33.

A CMOS image sensor comprises a substrate, a photo-active feature on the substrate, a photo-active feature on the substrate, at least one metal feature about the photo-active feature, a lens overlying the photo-active feature, and a low refractive index coating on the lens, the coating having (i) an amorphous structure of carbon and fluorine, (ii) CF2 bonds present in an atomic percentage of at least about 60%, and (iii) having a refractive index of less than about 1.33.

A CMOS image sensor comprises a substrate, an array of photo-active features on the substrate, twin stacks of metal features about each of the photo-active features, a color filter array comprising at least three different color filters disposed over the photo-active features, a plurality of lenses, each lens overlying a color filter, and a low refractive index coating on the lens, the coating having (i) an amorphous structure of carbon and fluorine, (ii) CF₂ bonds present in an atomic percentage of at least about 60%, and (iii) having a refractive index of less than about 1.33.

### DRAWINGS

These features, aspects and advantages of the present invention will become better understood with regard to the following description, appended claims and accompanying drawings, which illustrate examples of the invention. However, it is to be understood that each of the features can be used in the invention in general, not merely in the context of the particular drawings, and the invention includes any combination of these features, where:

FIG. 1 is a schematic cross-sectional view of a low refractive index coating deposited on photo-active features of a photo-active device formed on a substrate;

FIG. 2A is a schematic cross-sectional view of a photo-active device comprising a photo-active feature that is a front-illuminated CMOS image sensor composed of an array of three photodiodes that each have a different color filter and a microlens with a low refractive index coating thereon;

FIG. 2B is a schematic cross-sectional view of a photo-active device comprising a photo-active feature that is a back-illuminated CMOS image sensor;

FIG. 2C is a schematic cross-sectional view of a photoactive device comprising a photodiode;

FIG. 2D is a schematic cross-sectional view of another embodiment of a photodiode;

FIG. 3 is a flow chart of two exemplary processes for the deposition and treatment of a low refractive index coating on a substrate;

FIG. 4A is a graph of an X-ray Photoelectron Spectroscopy (XPS) spectra of a low refractive index coating deposited using a remote plasma deposition gas comprising C₄F₈, and showing the different carbon-fluorine bonds present in the coating;

FIG. 4B is a graph of an XPS spectra of a low refractive index coating deposited using a PECVD process using the same precursor gas, namely C₄F₈;

FIG. 4C is a graph of the XPS spectra of a spin-coated polytetrafluoroethylene (PTFE) film deposited by spin coating;

FIG. 5A is a plot of the measured refractive index versus atomic percentage of CF₂ bonds of the LRI coatings deposited by in-situ PECVD and remote plasma CVD processes;

FIG. 5B is a plot of the measured refractive index versus F/C ratio of the LRI coatings deposited by in-situ PECVD and remote plasma CVD processed;

FIG. 6A is a graph of an XPS spectra of a low refractive index coating deposited using a remote plasma CVD process with a deposition gas comprising the precursor gas C₄F₈;

FIG. 6B is a graph of an XPS spectra of a low refractive index coating deposited using a remote plasma CVD process with a deposition gas comprising the precursor gas C₃F₆O;

FIG. 7A is a graph of a Fourier Transformed Infrared Spectroscopy (FTIR) spectra of a low refractive index coating deposited using an in-situ PECVD process with a plasma formed in the process chamber, and showing a broad absorbance band at wavelengths of 1100 cm⁻¹ to 1400 cm⁻¹ that indicates an amorphous structure; and

FIG. 7B is a graph of an FTIR spectra a low refractive index coating deposited using a remote plasma CVD process with a plasma formed in a remote gas energizer, and showing sharp and distinct CF₂ peaks which indicate a low degree of cross-linking;

FIG. 8A is a schematic view of an embodiment of a substrate processing chamber comprising a remote plasma CVD chamber;

FIG. 8B is a schematic view of another embodiment of a remote plasma CVD chamber; and

FIG. 8C is a schematic view of a detailed section of the gas distributor of the remote plasma CVD chamber of FIG. 8B.

### DESCRIPTION

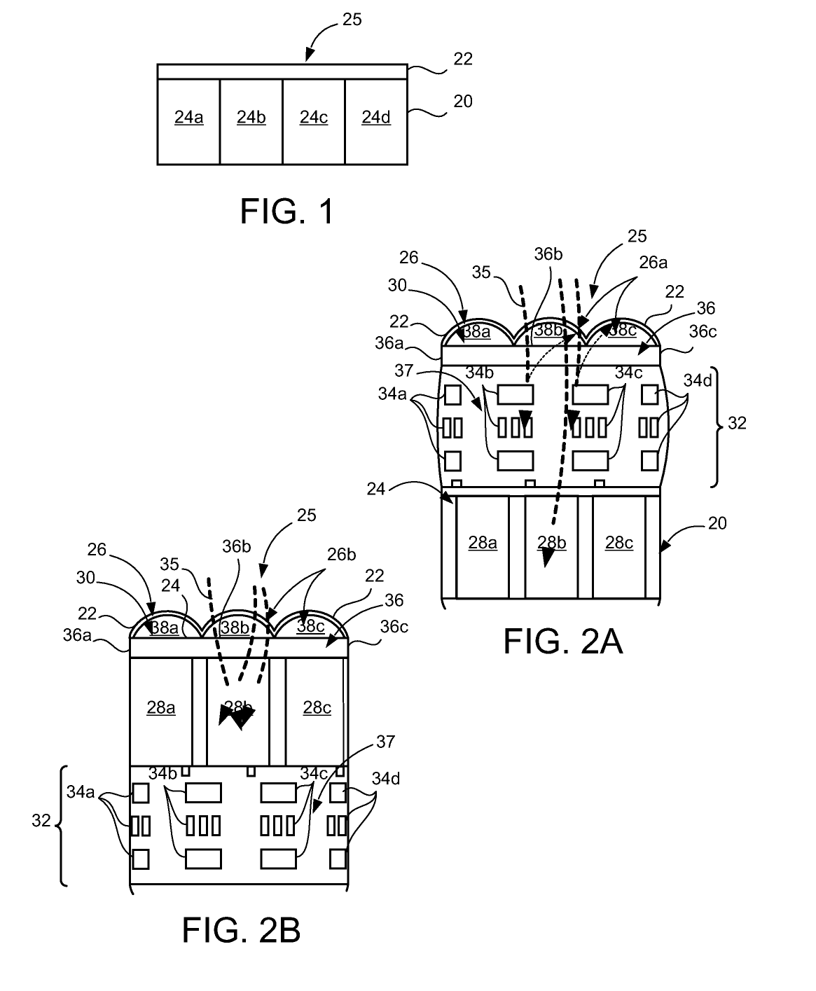

A low refractive index (LIR) coating 22 that serves as an anti-reflective coating overlying a photo-active feature 24 of a photo-active device 25, as shown in FIG. 1, is deposited on a substrate 20 at low temperatures by plasma enhanced chemical vapor deposition (PECVD). While “coating” is used to describe the fluorocarbon PECVD deposits, it should be understood that by coating it is meant any one of a continuous layer, a discontinuous layer, selective deposition on underlying features, and deposition of a layer followed by the etching of portions of the deposited layer. Further, the LIR coating 22 can be deposited directly on the photo-active device 25 or more typically on other features overlying the photo-active device 25, such as for example, a lens or window.

The substrate 20 can be, for example, a silicon wafer, a wafer of a III-V compound such as gallium arsenide, a germanium or silicon-germanium (SiGe)e wafer, an epi-substrate, a silicon-on-insulator (SOI) substrate, a display such as a liquid crystal display (LCD), a plasma display, an electroluminescence (EL) lamp display, or a light-emitting diode (LED) substrate. In certain applications, the substrate 20 may be a semiconductor wafer such as a silicon wafer having a diameter of 200 mm, 300 mm, or even 450 mm. In other applications, the substrate 20 can be a dielectric plate, such as polymer or glass panel, e.g., acrylics, polyimide, and borosilicate and phosphosilicate glass panels.

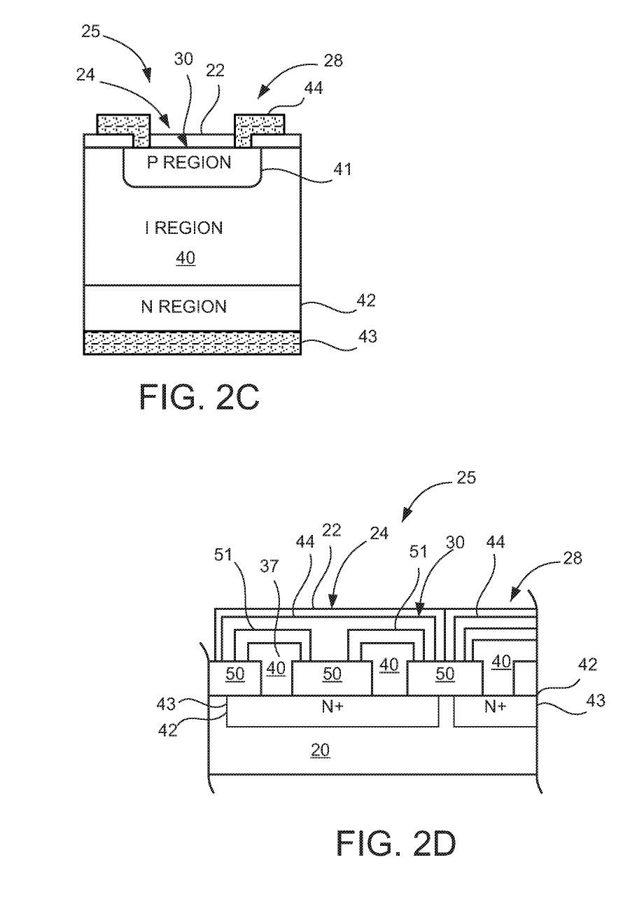

The photo-active device 25 can include one or more photo-active features 24 which can be, for example, image sensors or display pixels. For example, FIG. 2A shows a photo-active device 25 comprising a photo-active feature 24 that is a complementary metal-oxide semiconductor (CMOS) image sensor 26. In this version, the image sensor 26a comprises a front-illuminated CMOS image sensor 26a having an image receiving surface 30. The image sensor 26a comprises an array of three photodiodes 28a-c formed in a substrate 20 that is a silicon wafer. Each of the photodiodes 28a-c converts to electrons, any radiation or light which is incident on the image receiving surface 30 and which passes through to reach the photodiodes. A metal layer 32 comprises stacks of one or more metal features 34a-d aligned with the photodiodes 28a-c. The metal features 34a-d can serve as, for example, electrodes, guard rings and light gates. For example, in the version shown, twin stacks of adjacent metal features 34a,b or 34b,c or 34c,d are aligned along the light pathway, and positioned overlying, the three photodiodes 28a-c. A color filter array 36 comprises at least three color filters 36a-c, for example, a red filter (36a), blue filter (36b), and green filter (36c). Each of the color filters 36a-c are aligned along a light pathway of one of the photodiodes 28a-c. A lens 38a-c covers each color filter 36a-c and is also aligned to, and overlying, a photo-active feature 24, namely one of the photodiodes 28a-c.

A low refractive index coating 22 covers the image-receiving surface 30 of the image sensors 26. In this version, the LIR coating 22 covers the surfaces of the lenses 38a-c to serve as an anti-reflective coating. The LIR coating reduces light reflectivity arising from the mismatched in refractive indexes between air (RI_{AIR}=1) and the lenses 38a-c (RIₗₑₙₛ which is typically from 1.5 to 1.8). The optimal refractive index for the low refractive index coating 22 can be determined from the formula RI_{COATING}=(RI_{AIR}*RIₗₑₙₛ)^{1/2}. The optimal refractive index minimizes reflection and maximizes transmission at the lens-air interface, at a selected light wavelength, for example, at wavelengths of from about 400 to about 700 nm. Without the low refractive index coating 22, surface reflection of the incident light intensity can be 5% or even higher. With a low refractive index coating 22 having an RI_{COATING} of less than about 1.4, the surface reflection was found to be reduced to less than 3% or even less than 2%.

As another example, FIG. 2B shows a photo-active device 25 comprising a photo-active feature 24 that is also an image sensor 26 comprising a back-illuminated CMOS image sensor 26b. In this version, the image sensors 26b each include an underlying metal layer 32 comprising stacks of the metal features 34a-c. The substrate 20 is, for example, a silicon wafer that is thinned to less than 20 microns. The metal layer 32 is covered by an array of three photodiodes 28a-c which is formed in a substrate 20. A color filter 36 comprising a plurality of color filters 36a-c are formed over the image receiving surface 30, the color filters 36a-c comprising, for example red, green and blue filters. A lens 38a-c covers each of the color filters 36a-c of the photodiodes 28a-c. Again, the low refractive index coating 22 covers the image receiving surface 30 which is the surfaces of the lenses 38a-c to serve as an anti-reflective coating for the image sensor 26b.

An exemplary embodiment of a photo-active device 25 comprising a photo-active feature 24 that is a photodiode 28 is illustrated FIG. 2C. The photodiode 28 generally comprises a P-N junction which are can be a P-I-N or N-I-P junction, which have a thicker, middle, intrinsic region (I-region) 40 between the P-region 41 and N-region 42. The intrinsic region 40 is where most of the incident photons are absorbed to generate carriers that efficiently contribute to the photocurrent. The intrinsic region 40 may be either completely undoped or lightly doped, such as doped to form a lightly doped N-region. The photodiode 28 comprises (i) an underlying bottom electrode 43, (ii) a N-region 42 overlying the bottom electrode, (iii) an I-region 40 over the N-region 42, (iv) a P-region 41 embedded into the I-region 40, (v) a top electrode 44 contacting the P-region 41, and (v) a low refractive index coating 22 over the image receiving surface 30 of the P-region 41, which serves as an anti-reflective coating for incident radiation such as optical light, infrared or ultraviolet radiation. In another version, the photodetector 28 can also be an avalanche photodiode, which has a similar structure to that of the more commonly used PN/PIN/NIP structures. However, as the avalanche photodiode is operated under a high level of reverse bias with a guard ring (not shown) placed around the perimeter of the PN/PIN/NIP junction to reduce or prevent surface breakdown mechanisms.

The materials used to fabricate the photodiode 28 determine its light sensitive properties, namely, the wavelength of light to which the photodiode responds and the signal to noise ratio. The wavelength sensitivity occurs because only photons with sufficient energy to excite an electron across the bandgap of the material will produce significant energy to develop a current from the photodiode 28. For example, the wavelength sensitivity of germanium is from about 800 to about 1700 nm, indium gallium arsenide is from about 800 to about 2600 nm, lead sulphide is from about to about 3005 nm, and of silicon is from about 190 about 1100 nm.

Another exemplary structure of a photodiode 28 comprising a P-I-N structure is illustrated in FIG. 2D. This photodiode 28 includes (i) one or more bottom electrodes 46 which also serve as the N-regions 44, and which can be N⁺ features composed of a semiconducting material implanted with N⁺ ions, (ii) spaced-apart dielectric features 50 that overlie adjacent N⁺ features to form the separation gaps 37, (iii) an intrinsic region 40 comprising lightly N+-doped material that fills and covers the gaps 37 between the dielectric features 50, (iv) P-regions 42, such as P⁺ regions, comprising a doped semiconducting material, (v) one or more top electrodes 48, and (vi) a low refractive index coating 22 covering the image receiving surface 30 of the photodiode 28. The N-regions 44, are formed, for example, in a silicon wafer and are composed of portions of the silicon wafer implanted with N+ ions, such as phosphorous, by conventional ion implantation processes. The dielectric features 50 are formed by depositing a silicon dioxide layer by CVD, planarizing the silicon dioxide layer with chemical mechanical polishing, and then etching holes into the silicon dioxide layer to form the gaps 37 between the features 50 with conventional photolithography and etching methods. The intrinsic regions 40 lightly N+ doped material can be CVD deposited polysilicon ion implanted with phosphorous. The P+ regions 42 can be for example, silicon, polysilicon or germanium, doped with boron or aluminium by ion implantation. The top electrodes 48 can be made from conducting material, such as polysilicon or indium tin oxide (In₂O₃—SnO₃—ITO). The structure and fabrication method as described are suitable for P-I-N photodiodes; however, the same method can be used to fabricate N-I-P photodiodes by simply changing the n-doped and p-doped layers to p-doped and n-doped layers, respectively.

The photo-active device 25 can also be an active-pixel sensor (APS) comprising photo-active features 24 each of which include an image sensor 26 composed of an integrated circuit containing an array of pixel sensors. Each pixel sensor contains a photodiode and an active amplifier. Common active pixel sensors include the CMOS APS used most commonly in cameras such as cell phone cameras, web cameras and in some DSLRs. The pixel sensors are also produced by conventional CMOS processes, and consequently, also known as CMOS sensors.

For any of the versions of photo-active devices 25 described herein, a low refractive index coating 22 is positioned in the light passageway leading to a photo-active feature 24. For example, the LIR coating 22 can be deposited on the lenses 38a-c of the front and back-illuminated CMOS image sensors 26a,b, respectively, as shown in FIGS. 2A and 2B. As another example, the LIR coating 22 can be deposited on the imaging surface of photo-active features 24 which are display pixels. In yet another example, the low refractive index coating 22 can be deposited on the light-receiving surface of photo-active features 24 comprising active-pixel sensors.

In one exemplary structure, the low refractive index coating 22 is deposited on CMOS image sensors 26 as described above, which had pixel sizes of about 1.4 microns or larger. After deposition of the LIR coating 22 on the image-receiving surfaces 30 of the image sensors 26, the surface reflection of incident light from the surfaces of the lenses 38a was determined to be less than about 2% at wavelengths of from about 400 to about 700 nm. The reflectivity of the lenses 38a-c was determined using the refractive index of the lens material. The light transmission results demonstrated that the light transmittance through the lens of the photo-active sensor increased by from about 3% to about 5% with the applied fluorocarbon coating 22. The light transmission of the fluorocarbon coating 22 was evaluated from the signal to noise ratio at each pixel color Still further, a quantum efficiency (QE) gain of from about 2% to about 3% was observed for the low refractive index coating. The signal to noise ratio was also observed to have increased in all three pixel colors. These results represented significant improvements over prior art anti-refractive coatings, such as silicon dioxide coatings.

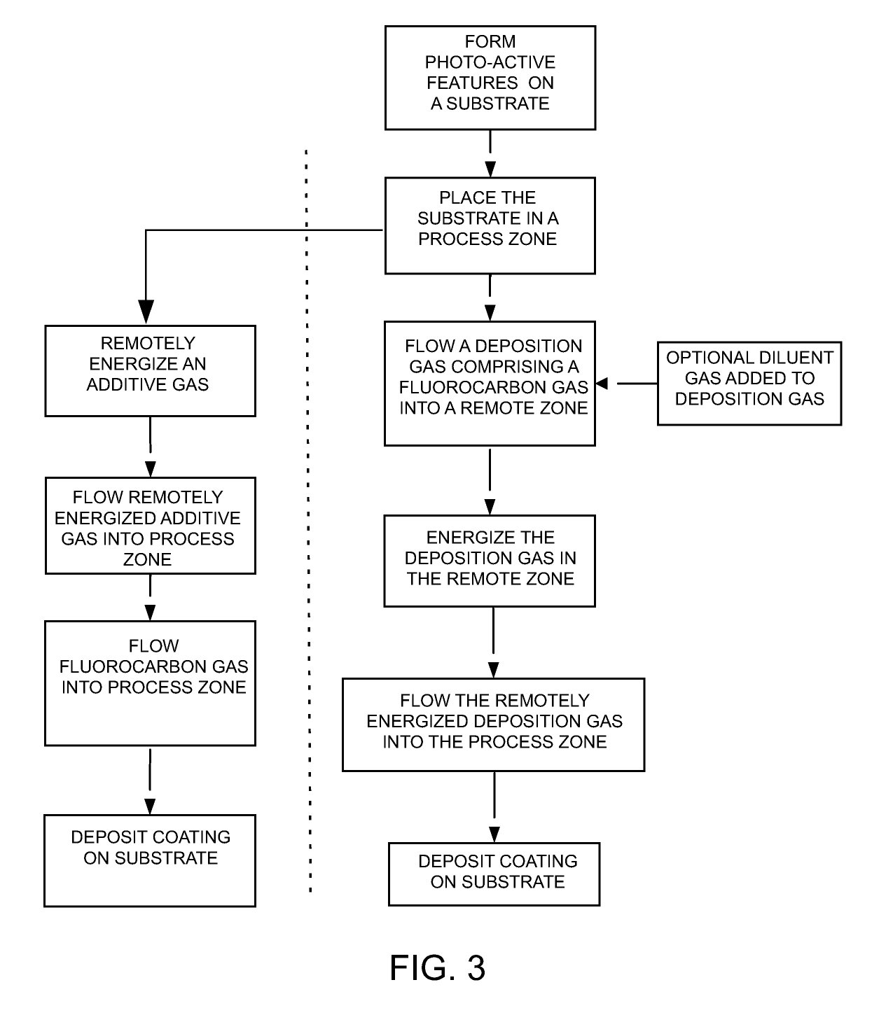

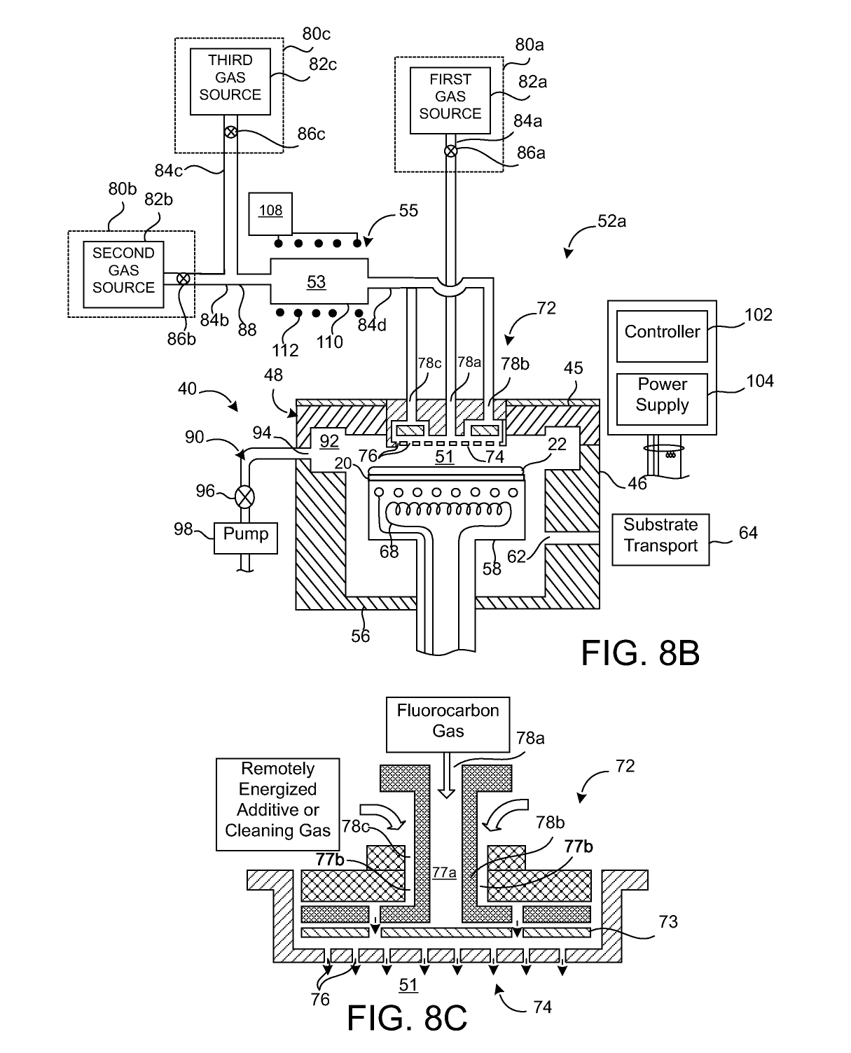

The low refractive index coating 22 was deposited on the substrate 20 by a remote plasma chemical vapor deposition (RP-CVD) process, as illustrated by the processes shown in the flowchart of FIG. 3. In the deposition processes, a substrate 20 comprising one or more photo-active features 24 is processed in a process zone 51 of an evacuated process chamber 52 of a substrate processing apparatus 50, 50a, such as the exemplary apparatuses shown in FIGS. 8A and 8B. During deposition, the substrate 20 is maintained at a temperature of less than about 240° C., or even from about 80° C. to about 200° C., or even about 40° C. These temperatures do not thermally degrade the photo-active features 24 of the substrate 20.

In one version of the deposition process, as shown in the right side of the flowchart of FIG. 3, a deposition gas comprising a fluorocarbon gas is introduced into a remote zone 53 of a remote gas energizer 55 of the apparatus 50. The fluorocarbon gas comprises carbon and fluorine in a ratio of carbon to fluorine of from about 1:1 to about 1:3. Suitable fluorocarbon gases include, for example, C₄F₆, C₄F₈ and C₃F₆O. A suitable flow rate for the fluorocarbon gas is from about 200 to about 2500 sccm, or even from about 100 to about 1100 sccm. However, the flow rate can depend on the size of the substrate 20 and the volume of the process zone 51 of the process chamber 52. The deposition gas may also include an additive gas to control the properties of the plasma generated from the fluorocarbon gas of the deposition gas. For example, the additive gas can improve the deposition uniformity of the LIR coating 22 by diluting the concentration of carbon and fluorine species in the process chamber 52, or by reacting with one or more of the carbon and fluorine gas or plasma species. The additive gas can also serve to energize and dissociate the carbon or fluorine atoms of the fluorocarbon gas for reaction via molecular collisions in the process zone 51. Suitable additive gases can include, for example, one or more of argon (Ar), helium (He), nitrogen (N₂), nitrogen trifluoride (NF₃), and ammonia (NH₃). The additive gas can also be an argon-helium mixture. The additive gas is typically provided in a larger volume than the fluorocarbon gas. For example, the additive gas can be added in a flow rate of from about 500 to about 10,000 sccm, or even from about 1000 to about 5000 sccm.

In another version, as shown in the left side of FIG. 3, a deposition gas comprising a fluorocarbon gas is introduced directly in the process zone 51 of a chamber 52a. The fluorocarbon gas comprises carbon and fluorine in a ratio of carbon to fluorine of from about 1:1 to about 1:3, and exemplary fluorocarbon gases include, for example, C₄F₆, C₄F₈ and C₃F₆O, at a flow rate of from about 200 to about 2500 sccm, or even from about 100 to about 1100 sccm. Separately, an additive gas is remotely energized in a remote zone 53 of a remote gas energizer 55, and then the energized gas is also flowed into the process zone 51, where it mixes with the fluorocarbon gas to deposit the coating 22 on the substrate 20. For example, the additive gases can include, for example, one or more of non-reactive gases such as argon (Ar) or helium (He), and reactive gases such as nitrogen (N₂), nitrogen trifluoride (NF₃), and ammonia (NH₃). The additive gas can be added in a flow rate of from about 500 to about 10,000 sccm, or even from about 1000 to about 5000 sccm.

The remote gas energizer 55 which is outside of, and distal and spaced apart from, the process chamber 52, comprises a remote zone 53 in which a deposition gas is energized. The deposition gas in energized by coupling energy to the deposition gas in a remote zone 53 to form a plasma. In one embodiment, RF energy is inductively coupled to the deposition gas by passing a current through a coil 112 wrapped around a cylinder 110 to inductively transfer RF energy to the deposition gas as it flows through the remote zone 53 in the cylinder 110. For example, the remote gas energizer 55 can be an Astron®-EX remote plasma source available from MKS Instruments, Andover, Mass. A power supply 108 that is electrically coupled to the coil 112 supplies a current of RF energy to the coil 112 at the desired power level. In one version, the current passed through the coil 112 has radio frequencies (RF) of from about 2 KHz to about 15 MHz, or even from about 10 MHz to about 15 MHz (e.g., about 13.6 MHz). A suitable power level is from about 100 W to about 9000 W. The remotely energized deposition gas is then flowed to the process zone 51 in the interior of the process chamber 52. The deposition gas is maintained at the pressure into the process zone 51 of the process chamber 52. For example, for the deposition gases described herein, a suitable pressure is from about 0.5 Torr to about 20 Torr, or even 1 Torr to about 10 Torr.

The remotely energized gas deposits a low refractive index coating 22 on the substrate 20 which has a significantly lower refractive index than other methods of depositing such films. The LIR coating 22 has an amorphous structure with a composition comprising carbon and fluorine. Generally, the LIR coating 22 has the composition CₓF_{y} with the presence of any one or more of CF, CF₂, CF₃, and C—CF bonds as described below. In one version, the remotely energized opposition gas deposits a LIR coating 22 having CF₂ bonds present in an atomic percentage of at least about 60%. The carbon to fluorine ratio and the percentage of CF₂ bonds was found to be determinative of the refractive index of the low refractive index coating 22 as explained below. In one version, the low refractive index coating 22 has the structure CₓF_{y}, where the ratio of y:x, namely the fluorine to carbon ratio is from about 1.8 to about 2. The low refractive index coating 22 deposited by the remote plasma deposition process also has a refractive index of less than about 1.33, or even from about 1.31 to about 1.33, at wavelengths of visible light, such as wavelengths of from about 400 to about 700 nm.

Typically, a number of LIR coating deposition processes are conducted to coat a plurality of substrates 20 of a batch of substrates, after which, a cleaning process is conducted to clean the interior surfaces of the process chamber 52. The cleaning process can also be conducted between processing steps in which different materials are deposited on a single substrate 20, such as a multilayer anti-reflective coating as described below. In the cleaning process, the substrate 20 is removed from the process zone 51 of the process chamber 52. Thereafter, a remotely energized cleaning gas, which is energized in the remote gas energizer 55, is introduced into the process zone 51 to clean the interior surfaces of the process chamber 52. For example, the cleaning gas can be energized in the remote gas energizer 55 by passing a current through the coil 112 at a power level of about 200 Watts to about 2000 Watts, or even 800 watts, and at a voltage frequency of about 13.56 MHz. In one version, the remotely energized cleaning gas comprises an oxygen-containing gas, such as nitrous oxide (N₂O) or oxygen (O₂). The cleaning gas can be provided in a volumetric flow rate of from about 100 to about 10,000 sccm, or even from about 300 to about 5,000 sccm. The cleaning gas is maintained in the process zone 51 at a pressure of from about 1 to about 10 Torr. For example, the cleaning gas can be energized in the remote gas energizer 55 by applying a current through the coil, the maximum power of which is 9 KW. The cleaning process is typically conducted for about 30 seconds to about 5 minutes.

Before or after the low refractive index coating deposition process, other deposition processes can be used to deposit underlayers or overlayers onto the low refractive index coating 22. For example, a multilayer anti-reflective coating can include the low refractive index coating 22 and other layers having different refractive indices. Still further, the other layers may include further low refractive index coatings of the same type, low refractive index coatings having different refractive indices, silicon dioxide coatings, or still other types of coating materials. For example, a first low refractive index coating 22 can be covered by, or have an underlayer of, a second coating comprising a silicon dioxide coating having a refractive index of about 1.46. The silicon dioxide coating can be deposited by a CVD process conducted in the same chamber or a different chamber. For example, the silicon dioxide coating can be deposited using a process gas comprising silane (SiH₄) and nitrous oxide (N₂O). In such a process, the silane is provided in a flow rate of from about 10 to about 1000 sccm; nitrous oxide is provided in a flow rate of from about 100 to about 10,000 sccm. The deposition gas is maintained in the process chamber 52 at a pressure of from about 1 to about 10 Torr. The deposition gas is energized by an RF generator. Each layer of silicon dioxide can have a thickness of from about 100 to about 1000 angstrom. The multilayer deposition process can also be repeated a number of times to achieve a multilayer comprising a plurality of low refractive index coatings 22 and silicon dioxide coatings. A suitable thickness for the cumulative multilayer anti-reflective coating can be from about 1000 angstroms to about 3000 angstroms.

Still further, while the fluorocarbon coating 22 is illustrated for an anti-reflective coating application, the fluorocarbon coating 22 can also be used for other applications. For example, the fluorocarbon coating 22 can be used as a hydrophobic underlayer for extreme ultra-violet (EUV) lithography. As another example, the fluorocarbon coating 22 can be used as a release layer to facilitate release of MEMS devices and for nano-imprint lithography.

### EXAMPLES

The following examples illustrate the deposition process, structure, and properties of the low refractive index coating 22. However, it should be understood that each of the process steps, structural features, and properties of the low refractive index coating 22 as described herein, can be used by themselves or in any combination with each other, and not merely as described in a particular example. Thus, the illustrative examples provided herein should not be used to limit the scope of the present invention.

Table I shows a comparison of the properties of low refractive index coatings 22 deposited by an in-situ plasma of a plasma enhanced chemical vapor deposition (PECVD) process and a remote plasma CVD process. The plasma enhanced CVD process was conducted in a process chamber (not shown) having process electrodes about a process zone in the interior of the chamber. The process electrodes were energized by capacitively coupling energy to the electrodes at an RF frequency of 13.6 MHz and a power level of from about 50 W to about 500 W. In the deposition process, the deposition gas was maintained at a pressure of from about 0.5 to about 10 Torr in the chamber. In the remote plasma CVD process, the deposition gas contained either C₄F₆, C₄F₈ or C₃F₆O, and additive gas comprising Ar and/or He in a flow rate of from about 500 to about 5000 sccm. In Table I, Dep. Rate is the coating deposition rate obtained in each process, R/2 Unif. % is given by (maximum thickness−minimum thickness)/mean thickness*50, n is the refractive index of the deposited coating 22 measured at wavelengths of 400 and 633 nm, conformality (%) is the thickness of coating 22 on the vertical side of microlens/thickness of coating 22 on top of lens, CF₂ content is the atomic percentage of CF₂ bonds present in the deposited coating 22, and F/C ratio is the fluorine to carbon ratio in the deposited coating 22.

TABLE I

| | In-Situ Plasma | Remote Plasma | Remote Plasma |
|---|---|---|---|
| | (PECVD) | Example 1 | Example 2 |
| Precursor | C₄F₈ | C₄F₈ | C₃F₆O |
| Dep. Rate (A/min) | 800 | 700 | 1000 |
| R/2 Unif. (%) | 3.5 | Center-thick | Center-thick |
| n at 400 nm | 1.393 | 1.33 | 1.32 |
| n at 633 nm | 1.375 | 1.32 | 1.32 |
| Conformality (%) | 98 | — | — |
| CF₂ Content (%) | 26.7 | 65 | 78 |
| F:C Ratio | 1.26 | 1.7 | 2.0 |

It should also be noted that both the in-situ PECVD and remote plasma deposition processes deposited a conformal coating at temperatures of less than 240° C. Still further, both deposition processes did not damage the temperature sensitive material of the lenses 38a-c of the image sensors 26. Also, both deposition processes were compatible with conventional patterning, etching and stripping processes.

Referring to Table I, the remote plasma CVD deposited coatings 22 had substantially lower refractive indexes compared to the coatings deposited by the in-situ PECVD process. It is believed that the remote plasma provides lower and more desirable refractive indexes because the remotely generated plasma dissociates the precursor gas into many radical fragments such as CF, CF₂ and CF₃. These radical fragments travel through a conduit pathway to reach the process zone of the process chamber. During traveling many charged ions recombine resulting in a higher percentage of neutral species in the energized gas by the time it reaches the substrate 22. As result, the low refractive index coating 22 deposited by the remote plasma method has a different chemical structure and composition than the coating 22 deposited by an in-situ PECVD process. Also, it is believed that the remote plasma deposition processes deposited coatings 22 can also have exhibit a graded refractive index when the coatings include deposited layers having lower refractive index at a bottom portion of the coating 22, and deposited layers having higher refractive indexes at a top portion of the coating.

Referring back to Table I, when comparing the deposition examples of the two different precursors used in remote plasma CVD process, the deposition gas composed of C₃F₆O and He—Ar provided slightly superior results than the deposition gas comprising C₄F₈ and He—Ar. The C₃F₆O (experiment 2) deposited a low refractive index coating 22 having a refractive index of 1.32 with an incident light wavelength of 400 nm, and the same refractive index of 1.32 at 633 nm. It was further observed that the C₃F₆O experiment deposited a coating 22 having an atomic percentage of CF₂ that was substantially higher at 78% than the atomic percentage of CF₂ present in the C₄F₈ process namely 65%, both of which was 2× to 3× higher than the % CF₂ ratio of the coating deposited by the in-situ PECVD process which was at 26.7%. Also, the fluorine to carbon (F:C) ratio of the coating deposited by the C₃F₆O experiment was higher at 2.0 than the F:C ratio of the coating deposited by the C₄F₈ process namely 1.7, both of which was substantially higher than the F:C ratio of the in-situ PECVD process at 1.26. These results indicated two things, first that the remote plasma was capable of depositing coatings 22 having a lower refractive index than the in-situ PECVD plasma process, and second that the refractive index of the coatings appear to have relationship of the CF₂ content and the F:C ratio within the deposited coating.

X-Ray photoelectron spectroscopy (XPS) analysis of the low refractive index coatings 22 deposited by a remote plasma CVD process and an in-situ PECVD process was then conducted. XPS was used to measure the elemental composition and chemical state of the elements that existed in the low refractive index coating 22 by irradiating a sample of the coating with a beam of X-rays in ultra-high vacuum (UHV) conditions while simultaneously measuring the kinetic energy and number of electrons that escaped from the top 1 to 10 nm of the material being analyzed.

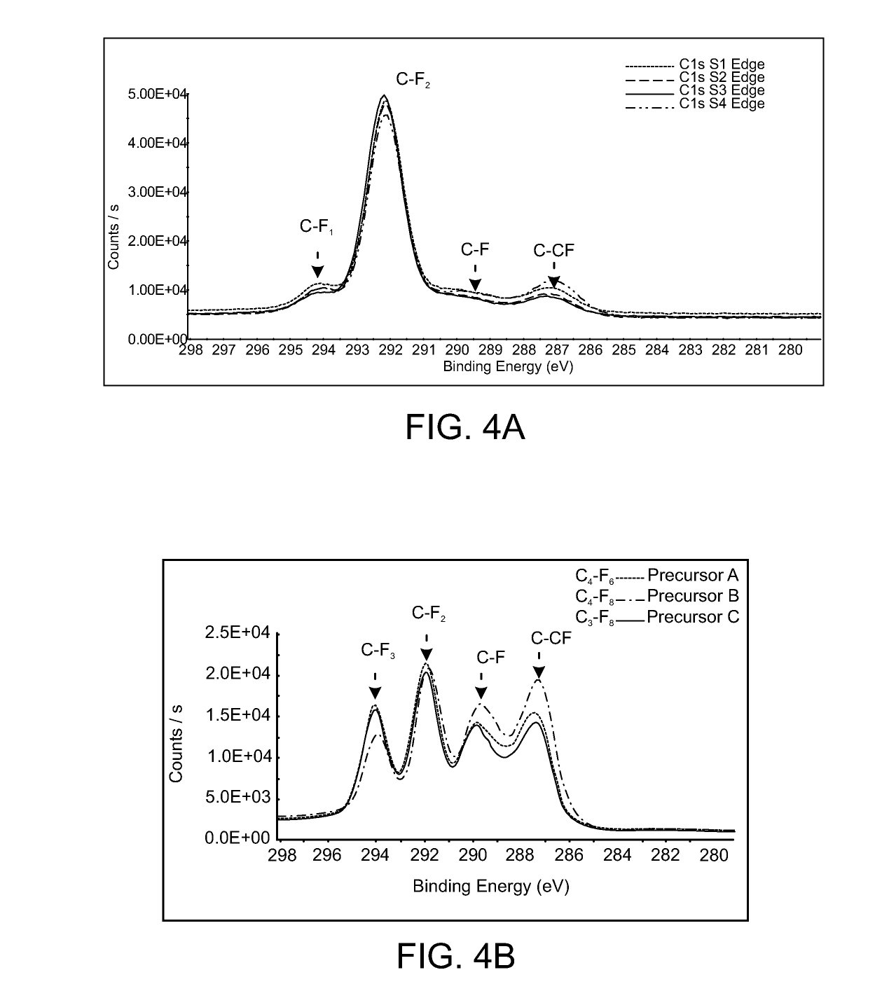

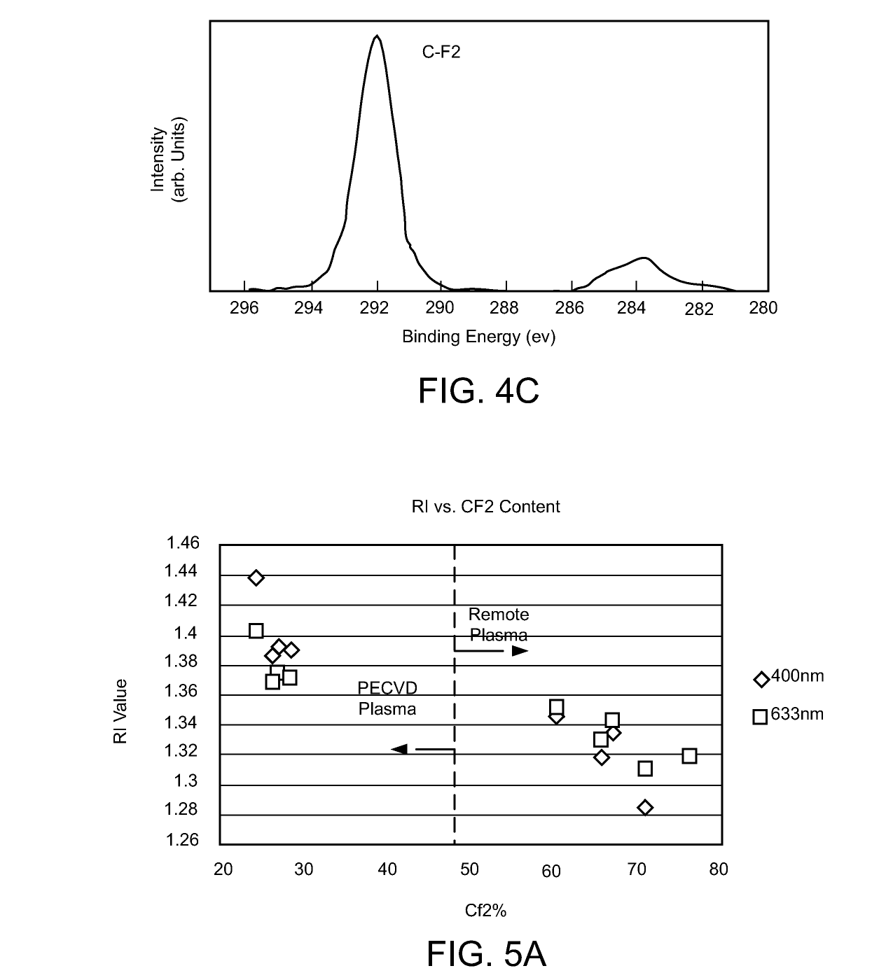

An XPS trace for the coating 22 deposited using a remote plasma deposition gas comprising C₄F₈ is shown in FIG. 4A to compare with the XPS trace for a coating 22 deposited using a PECVD process using the same precursor gas, as shown in FIG. 4B. The difference between the two traces demonstrates the much larger CF₂ peak at 292 eV that is evident in the coating 22 deposited using the remote plasma deposition process. In addition, the remote plasma deposition process exhibited the presence of, albeit sized much smaller, peaks for other bonding structures such as C—F (very small peak at 290 eV), CF₃ (small peak at 294 eV), and C—CF (small peak at 288 eV). In contrast, the PECVD process deposited a coating 22 having much larger peaks for the C—F, CF₃, and C—CF bonds, relative to the size of the CF₂ peak. While the atomic percentage of CF₂ bonds in still the highest peak in the coating deposited by the PECVD process, it is much smaller than the atomic percentage of CF₂ bonds present in the coating 22 deposited by the remote plasma process.

Still further, an XPS spectrum of a spin-coated polytetrafluoroethylene (PTFE) film deposited by spin coating is shown in FIG. 4C. It is seen that the spin-coated film is essentially a single large peak at 292 eV corresponding to the CF₂ bond structure. Thus it is apparent that the conventional PTFE films deposited by spin-coating have an entirely different internal bonding structure than the coatings 22 deposited by PECVD or remote plasma CVD. Specifically, the PECVD and remote plasma CVD coatings exhibit bonding peaks for the C—F, CF₃, and C—CF bonds, in addition to a large bonding peak for CF₂. Thus there is a structural difference between the PTFE films and the coatings 22 deposited by PECVD or remote plasma, relating to the percentage of C—F, CF₃, and C—CF bonds. The presently developed, the refractive index coatings 22 can be defined as having (i) C—F bonds in an atomic percentage of at least about 20, or even at least about 8, (ii) CF₃ bonds in an atomic percentage of at least about 10, or even at least about 6, (iii) CF₂ bonds in an atomic percentage of at least about 60, or even at least about 70, and (iv) C—CF bonds in an atomic percentage of at least about 10, or even at least about 2.

Table II shows a comparison of the characteristics of coatings 22 deposited using an in-situ PECVD plasma and a remote plasma CVD process. Different precursor or deposition gases were used in each of these processes. The F:C ratio and atom % of CF₂ present in the deposited coating was measured. The PECVD process was conducted in a process chamber (not shown) having process electrodes about a process zone in the interior of the chamber, and with the general process conditions described above. The PECVD process was conducted using four different compositions of deposition gas that included as a precursor gas either one of C₄F₆, C₄F₈, C₃F₈ and C₃F₆O, as well as additive gas comprising He—Ar. The remote plasma processes were conducted using a deposition gas that contained either C₄F₈ or C₃F₆O, as well as additive gas comprising He—Ar.

TABLE II

| | |
|---|---|
| In-Situ Plasma | Remote Plasma |

| Precursor | F:C Ratio | CF₂ % | F:C Ratio | CF₂ % |
|---|---|---|---|---|
| C₄F₆ | 1.08 | 24.1 | | |
| C₄F₈ | 1.26 | 26.7 | 1.6-1.8 | 60-70 |
| C₃F₈ | 1.41 | 26.1 | | |
| C₃F₆O | 1.41 | 28.4 | 2.0 | 76-80 |

It is seen from Table II, that the remote plasma CVD process deposited coatings 22 having a generally much higher F:C ratio ranging from about 1.6 to about 2.0. The higher F:C ratios also correlated to higher atomic percentages of CF₂ bonds present in the coating 22. For example, the remote plasma deposition process that used a deposition gas comprising C₃F₆O deposited a low refractive index coating 22 having the highest F:C ratio of 2.0 and the highest atomic percentage of CF₂ of 76-80%. From Table II, the C₃F₆O deposited coating also had the lowest refractive index of 1.32 at both wavelengths of 400 and 633 nm. Similarly, the remote plasma deposition process that used a deposition gas comprising C₄F₈ and which also deposited a low refractive index coating 22 had the second highest F:C ratio of 1.6 to 1.8 and the second highest atomic percentage of CF₂ of 60-70%. In contrast, the in-situ PECVD deposition processes which deposited coatings 22 having refractive indices of from about 1.43 to about 1.4, had the much lower F:C ratios of 1.08 to 1.41 and correspondingly lower atomic percentages of CF₂ of 24.1 to 28.4%.

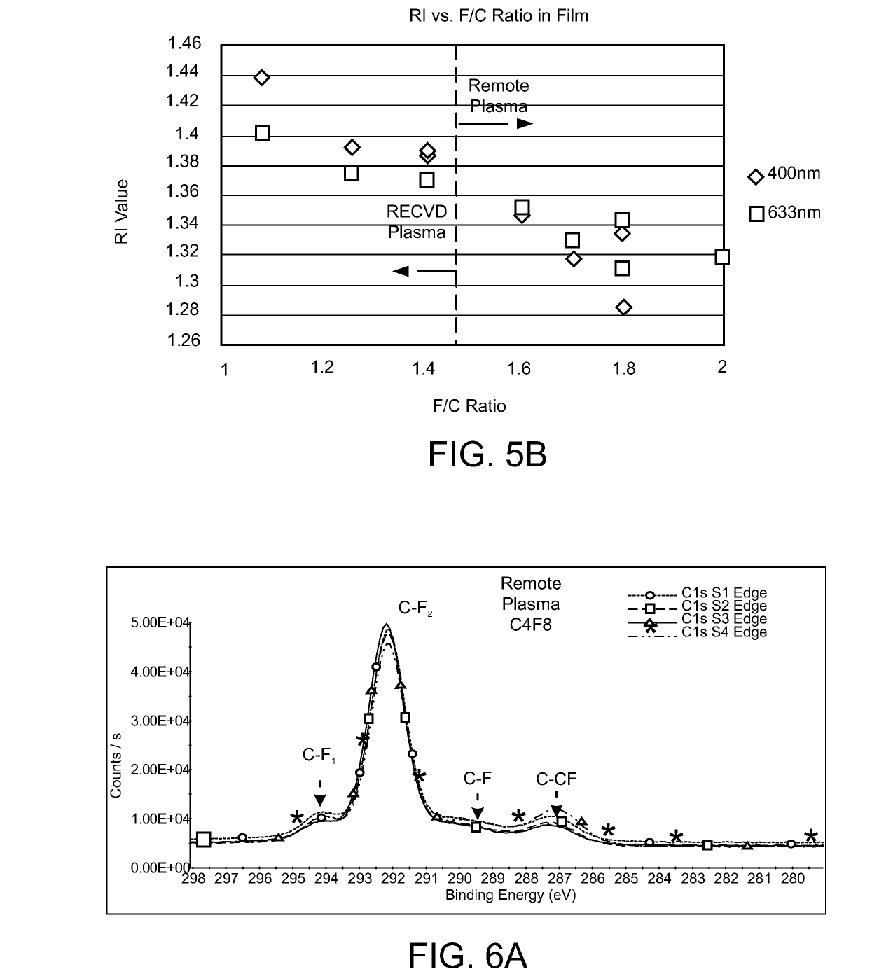

The relationship between the measured refractive index and atomic percentage of CF₂ bonds of the coatings 22 deposited by the in-situ PECVD and remote plasma CVD process is shown in FIG. 5A. As seen, the remote plasma deposition process yielded substantially lower refractive indices than the in-situ PECVD process. Still further, in both processes, the refractive index appears to be a linear function of the atomic percentage of CF₂ bonds present in the coatings 22. Similarly, FIG. 5B shows the relationship between the measured refractive index and F:C ratio (F/C) atomic of the coatings 22 deposited by the in-situ and remote plasma processes. Again, in both processes, the refractive index appears to be a linear function of the F:C ratio of the coatings 22. These findings are important, as they indicate that the refractive index of the deposited coating 22 can be set to a desired value by controlling the atomic percentage of CF₂ bonds or the F:C ratio of the deposited coating.

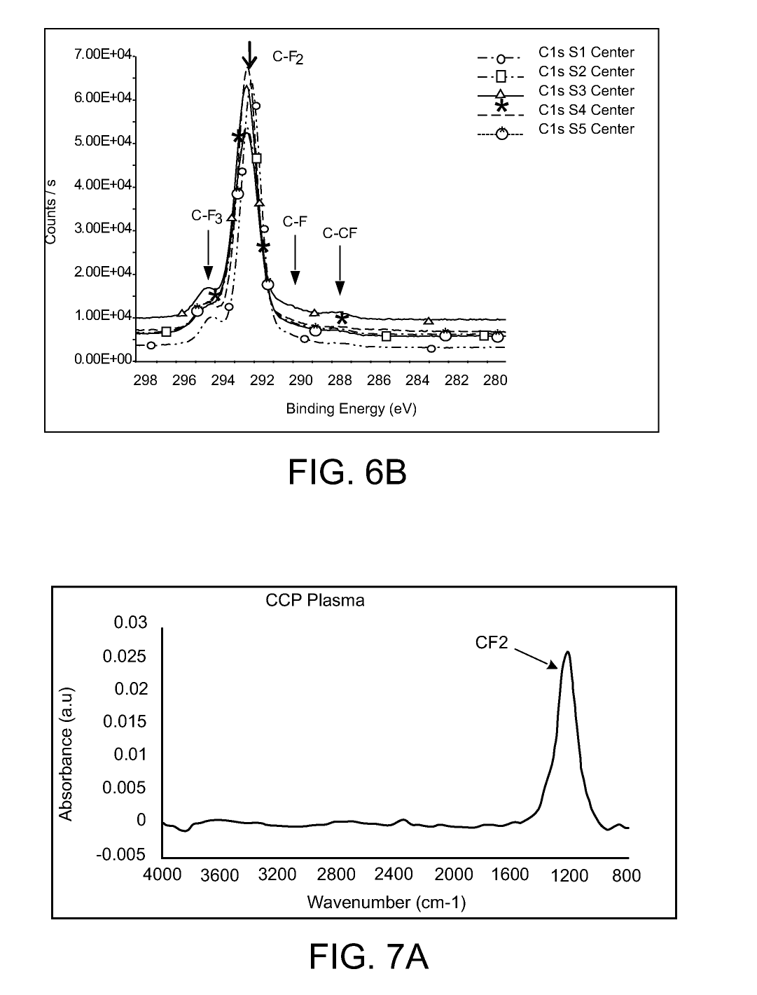

X-Ray photoelectron spectroscopy (XPS) analysis of the low refractive index coatings 22 deposited by the remote plasma process using either C₄F₈ or C₃F₆O was then conducted. FIG. 6A shows the XPS trace for the coating 22 deposited using a deposition gas comprising C₄F₈, while FIG. 6B shows the XPS trace for a coating 22 deposited using a deposition gas comprising C₃F₆O. The CF₂ bonds in the low refractive index coating 22 which had an intensity peak at about 292 eV appeared be highest when the process gas contained C₃F₆O. This demonstrates the higher atomic percentage of CF₂ that is present in the coatings deposited using C₃F₆O with remote plasma deposition in comparison to the coatings deposited using C₄F₈ and remote plasma. Generally, the RI_{COATING} (refractive index of the coating) decreased in the order of C₄F₈>C₃F₆O, which was consistent with the increase in CF₂ and F:C ratio. It should also be noted that the coatings 22 deposited using C₃F₆O by remote plasma deposition were also harder than the coatings deposited using C₄F₈. In both coatings, the presence of CF, C—CF and CF₃ bonds was also detected.

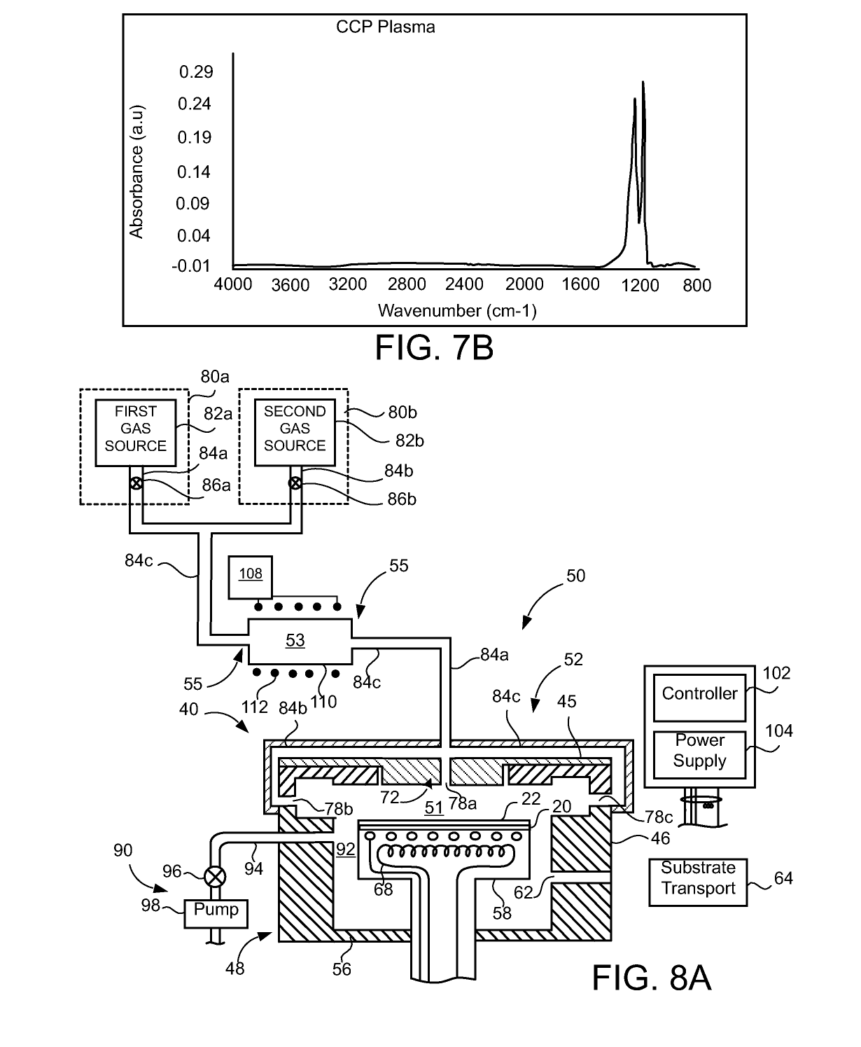

Fourier Transformed Infrared Spectroscopy (FTIR) was also conducted on a low refractive index coating 22 deposited by a in-situ PECVD process and a remote plasma CVD process. FIG. 7A is the FTIR spectrum of a LIR coating 22 deposited by the in-situ PECVD process, and showing a broad absorbance band at wavelengths of 1100 to 1400 cm⁻¹ which indicates an amorphous structure. FIG. 7B is the spectrum of a LIR coating 22 deposited by a remote plasma CVD process showing distinct CF2 peaks which indicate that the film has highly ordered CF2 bonds with low degree of cross-linking. These results indicate that the structure of the deposited coating 22 is distinctly different between the two deposition processes.

### Deposition Apparatus

The coating deposition processes described above can be performed in a substrate processing apparatus 50, an exemplary embodiment of which is illustrated in FIG. 8. The substrate processing apparatus 50 is provided to illustrate an exemplary deposition apparatus; however, other deposition apparatus my also be used as would be apparent to one of ordinary skill in the art. Accordingly, the scope of the invention should not be limited to the exemplary deposition apparatus described herein. Generally, the substrate processing apparatus 50 comprises one or more chemical vapor deposition chambers 52 suitable for processing a substrate 20 such as a silicon wafer or display. A suitable apparatus is a Producer®-DARC or ETERNA type apparatus from Applied Materials, Santa Clara, Calif. A suitable apparatus 50 comprising a chamber 52 is illustrated for example in US patent Pub. No. 2012/0073501A1, entitled “Process Chamber For Dielectric Gapfill” to Lubomirsky et al., filed on Sep. 29, 2011, which is incorporated by reference herein and in its entirety. The process chamber 52 may be one of a number of identical chambers, or different process chambers, all of which are coupled to a semiconductor substrate processing platform such as a CENTURA® processing platform, available from Applied Materials, Inc. Santa Clara, Calif.

As shown, the apparatus comprises a process chamber 52 having enclosure walls 48, which include a ceiling 45, sidewalls 46, and a bottom wall 56, that enclose a process zone 51. The ceiling 45 can be dome shaped as shown, and fabricated from a dielectric material such as quartz, aluminum oxide or other ceramic materials. The process chamber 52 may also comprise a liner (not shown) that lines at least a portion of the enclosure walls 48 about the process zone 51. For processing a substrate 20 comprising a 300 mm silicon wafer, the process chamber 52 can have a volume of from about 20,000 to about 30,000 cm³. It is also contemplated that the processing methods described herein may be practiced in other suitably adapted chambers, including those from other manufacturers, and thus, the claims should not be limited in scope to the exemplary embodiments described herein.

During a process cycle, a substrate support 58 in the chamber 52 is lowered, and a substrate 20 is passed through an inlet port 62 of the process chamber 52 and placed on the support 58 by a substrate transport 64, such as a robot arm. The substrate support 58 can include an electrostatic or vacuum chuck to retain the substrate 20 on a substrate receiving surface of the substrate support 58 during processing. The substrate support 58 may also comprise one or more rings, such as deposition rings and cover rings (not shown), that at least partially surround a periphery of the substrate 20 on the support 58. The substrate support 58 can also be heated by heater 68, which can be an electrically resistive heating element embedded in the substrate support (as shown), a heating lamp underneath the support 58 (not shown), or the plasma itself. In these processes, the substrate temperature can be controlled, for example, using the heater 68 (which can also be a chiller) or by supplying a heat transfer fluid to a fluid conduit heat exchanger (not shown) in the substrate support 58, to heat or cool the substrate 20.

The substrate support 58 can be moved between a lower position for loading and unloading and an adjustable upper position for processing of the substrate 20. For example, after a substrate 20 is loaded onto the substrate support 58 for deposition of a low refractive index coating 22 the substrate support 58 is raised to a processing position that is closer to the gas distributor 72 to provide a desired spacing gap distance between the bottom surface of a gas distributor 72 and the substrate processing surface of the substrate resting on the substrate support 58. For example, this gap distance can be set to be from about 7 mm (about 300 mils) to about 40 mm (about 1600 mils). The substrate support 58 may also be rotated during deposition to obtain more uniform coatings.

The gas distributor 72 delivers a process gas composition to the process chamber 52. In this chamber, the gas distributor comprises a plurality of gas outlets 78a-c for dispersing process gas into the process zone 51. A plurality of gas supplies, such as for example, the exemplary first and second gas supplies 80a,b (or additional gas supplies) each provide a component of the process gas to the gas distributor 72 via the remote gas energizer 55. The gas supplies 80a,b each comprise a gas source 82a,b, one or more gas conduits 84a,b, and one or more gas valves 86a,b. For example, in one version, the first gas supply 80a comprising a first gas source 82a holding for example a fluorocarbon gas, a first gas conduit 84a, and a first gas valve 86a. The second gas supply 80b comprises a second gas source 82b holding for example an additive gas, a second gas conduit 84b and a second gas valve 86b. The deposition gas comprises a fluorocarbon gas from the first gas supply 82a and a diluent or reactive gas from the second gas supply 82b, which are mixed together in the gas manifold 88. In one version, the fluorocarbon gas comprises either C₄F₆, C₄F₈ or C₃F₆0, and argon. Instead of the additive gas, the second gas supply 80b, such as NF₃ or even argon, which is remotely energized in the remote gas energizer 55, can be used to clean the interior surfaces of the chamber 52.

The mixed process gas is energized in a remote gas energizer 55 disposed above or directly on the top of the chamber 52 and which is fluidly coupled to the chamber 52 via the gas conduit 84c. The remote gas energizer 55 is a cylinder 110 having a coil 112 wrapped around the cylinder 110 to inductively transfer RF energy to the deposition gas passing through the cylinder 110. For example, the remote gas energizer 55 can be an Astron®-EX remote plasma source available from MKS Instruments, Andover, Mass. A power supply 108 is electrically coupled to the coil 112 of the remote gas energizer 55 to apply RF energy at a power level of from about 100 W to about 1000 W. In this version, the pre-mixed deposition gas is energized as it passes through the cylinder 110 of the remote gas energizer 55 by RF energy inductively coupled to the deposition gas by the coil 112.

The energized deposition gas is passed to the process zone 51 of the process chamber 52 by the gas conduits 84a-c which can form a T-shaped conduit to distribute the energized deposition gas across the substrate 20. For example, the gas conduits 84a-c can end in a top positioned gas outlet 78a, and a plurality of side outlets 78b,c and others which are positioned along the side of the substrate support 58. The gas conduits 84a-c can also be separated from another to separately energize and/or separately deliver, for example, reactive gases, precursor gases and diluent gases.

The process chamber 52 also comprises a gas exhaust 90 to remove spent gas and byproducts from the process chamber 52 and maintain a predetermined pressure of deposition or treatment gas in the process zone 51. In one version, the gas exhaust 90 includes a pumping channel 92 that receives spent gas from the process zone 51, an exhaust port 94, a throttle valve 96 and one or more exhaust pumps 98 to control the pressure of gas in the process chamber 52. The pumping channel 92 can be located at the side of the substrate support 58 as shown or at the bottom wall 56 of the chamber. The exhaust pumps 98 may include one or more of a turbo-molecular pump, cryogenic pump, roughing pump, and combination-function pumps that have more than one function. The deposition gas pressure is controlled by controlling a gas exhaust 90, which is controlled by setting the opening size of a throttle valve 96 which connects an exhaust port 94 and piping from the process chamber 52 to an exhaust pump 98. The throttle valve 96 and various mass or volumetric flow meters can also be adjusted during the deposition process to keep the gas pressure and flow rates stable.

The process chamber 52 can also comprise an inlet port or tube (not shown) through the bottom wall 56 of the process chamber 52 to deliver a purging gas into the process chamber 52. The purging gas typically flows upward from the inlet port past the substrate support 58 and to an annular pumping channel. The purging gas is used to protect surfaces of the substrate support 58 and other chamber components from undesired deposition during the processing. The purging gas may also be used to affect the flow of gas in a desirable manner.

A controller 102 is also provided to control the operation and operating parameters of the process chamber 52. The controller 102 may comprise, for example, a processor and memory. The processor executes chamber control software, such as a computer program stored in the memory. The memory may be a hard disk drive, read-only memory, flash memory, or other types of memory. The controller 102 may also comprise other components, such as a floppy disk drive and a card rack. The card rack may contain a single-board computer, analog and digital input/output boards, interface boards, and stepper motor controller boards. The chamber control software includes sets of instructions that dictate the timing, mixture of gases, chamber pressure, chamber temperature, microwave power levels, high frequency power levels, support position, and other parameters of a particular process.

The process chamber 52 also comprises a power supply 104 to deliver power to various chamber components such as, for example, an electrode of an electrostatic chuck (not shown) in the substrate support 58, the heater 68 of the substrate support 58, or other chamber components. For example, the power supply 104 can include a heater power source to provide an appropriate controllable voltage to the heater 68 with thermostats or thermocouples connected to the substrate support 58. The power supply 104 can also include the source of power for other chamber components, for example, motors, robots, substrate transport, of the process chamber 52. The process chamber 52 can also include one or more temperature sensors (not shown) such as thermocouples, RTD sensors, or interferometers to detect the temperature of surfaces such as component surfaces or substrate surfaces within the process chamber 52. The temperature sensor is capable of relaying its data to the chamber controller 102 which can then use the temperature data to control the temperature of the processing process chamber 52, for example, by controlling the heater 68 in the substrate support 58.

Another version of a substrate processing apparatus 50a suitable for depositing the low refractive index coatings 22 is shown in FIG. 8B. The apparatus 58 comprises a process chamber 52a having a gas distributor 72a which separates the flow paths of different components of the process gas, for example, the fluorocarbon gas and diluent/reactive gas, so that only the diluent gas or the reactive gas is energized in the remote gas energizer 55.

In one version of the chamber 52a, the gas distributor 72a comprises a blocker plate 73 and faceplate 74 lying below a gas passageway manifold 75, as shown in the more detailed schematic of FIG. 8C. The gas passageway manifold 75 comprises a plurality of gas passageways 77a,b, including a gas passageway 77a that is used to pass fluorocarbon gas from the first gas source 80a down the center of the gas distributor 72, and a gas passageway 77b that is used to pass an additive gas during the deposition process, or a cleaning gas during a cleaning process, from the second and third gas sources 82b,c respectively. The gas passageway 77a and 77b are separated from one another so that the energized additive gas which passes through the gas passageway 77b does not mix with the fluorocarbon gas passed through the gas passageway 77a, until the two gases meet about the blocker plate 73 and faceplate 74. The energized additive gas and the un-energized fluorocarbon gas mix around and about the blocker plate 73 and then passed through the spaced apart gas holes 76 in the faceplate 74 to be distributed uniformly across the substrate 20 in the process zone 51. The gas distributor 72a serves to both control the mixing of the energized additive gas with the un-energized fluorocarbon gas and spread the mix gases across the surface of the underlying substrate 24 to get better deposition thickness uniformity across the substrate surface.

The chamber 52a comprises a gas outlet 78a for dispersing a stream of process gas from the first gas supply 80a comprising a first gas source 82a containing a fluorocarbon gas and/or additive gas such as He or Ar, via a first gas conduit 84a and first gas valve 86a, into the gas passageway 77a and ultimately through the gas holes 76 of the faceplate 74. The first and second gas supplies 80a,b, provide an additive gas such as a diluent or reactive gas during deposition, or a cleaning gas during cleaning, for energizing in the remote gas energizer 55. The gas supplies 80a,b each comprise a gas source 82a,b, one or more gas conduits 84a,b, and one or more gas valves 86a,b. For example, in one version, the second gas supply 80b comprises a second gas source 82b holding an additive gas, a second gas conduit 84b and a second gas valve 86b. The third gas supply 82c comprises a third gas source 80c for holding a cleaning gas, a third gas conduit 84c, and a third gas valve 86c. The additive or cleaning gas is energized in the remote gas energizer 55 disposed above or directly on the top of the chamber 52a and which is fluidly coupled to the chamber via the gas conduit 84d. The remote gas energizer 55 as the same configuration as previously described.

In another version of the chamber 52a, the gas distributor 72a comprises gas conduits 84a-c which are T-shaped to distribute the energized deposition gas across the substrate 20 as, for example, shown in FIG. 8A. In this version, the gas conduits 84a-c end in a top positioned gas outlet 78a, and a plurality of side outlets 78b,c positioned along the side of the substrate support 58, again as shown in FIG. 8A. In this version, the gas conduits 84a-c are separated from another to separately energize and/or separately deliver, for example, any one or more of a reactive gas, precursor gas and diluent gas. For example, the first gas source 80a can provide fluorocarbon gas to the conduit 84a which passes the fluorocarbon gas directly into the gas outlet 78a without energizing the gas. The second and third gas sources 80b,c respectively, can provide an additive gas comprising for example, a reactive gas and a diluent gas such as argon, to the conduits 84a,b, which then pass the additive gas to the remote gas energizer 55 for energizing, then the energized gas is passed through the sidewall gas outlets (such as for example, the gas outlets 78a,b shown in FIG. 8A) to the chamber 52a. In this chamber 52a, during deposition of the low refractive index coating 22, the additive gas is energized in the remote gas energizer 55 and subsequently mixed with the un-energized fluorocarbon gas in the chamber 52a. During cleaning of the chamber 52a, a cleaning gas, such as NF₃ and O₂, is energized by itself in the remote gas energizer 55 and introduced into the process chamber 52a to clean the interior surfaces of the chamber 52a.

Although exemplary embodiments of the present invention are shown and described, those of ordinary skill in the art may devise other embodiments which incorporate the present invention and which are also within the scope of the present invention. Furthermore, the terms below, above, bottom, top, up, down, first and second and other relative or positional terms are shown with respect to the exemplary embodiments in the figures and are interchangeable. Therefore, the appended claims should not be limited to the descriptions of the preferred versions, materials, or spatial arrangements.

What is claimed is:

1. A method of depositing a low refractive index coating on a photo-active feature on a substrate, in a process chamber having a process zone, the process chamber being coupled to a remote gas energizer which is outside the process chamber, the method comprising:
(a) forming a substrate having one or more photo-active features thereon;
(b) placing the substrate in the process zone;
(c) flowing a deposition gas through the remote gas energizer, the deposition gas comprising a fluorocarbon gas and an additive gas;
(d) energizing the deposition gas by inductively coupling RF energy to the deposition gas while the deposition gas flows through the remote gas energizer; and
(e) flowing the remotely energized deposition gas into the process zone to deposit the low refractive index coating on the substrate.

2. A method according to claim 1 wherein (d) comprises applying the RF energy at a power level of from about 100 W to about 9000 W.

3. A method according to claim 2 comprising applying the RF energy at a frequency of from about 2 KHz to about 15 MHz.

4. A method according to claim 1 wherein the remote gas energizer comprises a cylinder having a coil wrapped around the cylinder, and wherein (d) comprises applying an RF current to the coil.

5. A method according to claim 1 wherein (b) comprises maintaining the substrate at a temperature of less than about 240° C.

6. A method according to claim 1 wherein in (c), the fluorocarbon gas comprises at least one of C₄F₆, C₄F₈ and C₃F₆O.

7. A method according to claim 1 wherein in (c), the fluorocarbon gas is introduced into the remote gas energizer at a flow rate of from about 50 to about 5000 sccm.

8. A method according to claim 1 wherein in (c), the deposition gas comprises an additive gas comprising one or more of argon, helium, nitrogen, nitrogen trifluoride, and ammonia.

9. A method according to claim 8 wherein the additive gas is introduced into the remote gas energizer at a flow rate of from about 50 sccm to about 5000 sccm.

10. A method according to claim 1 wherein in (d), the deposition gas in the process zone is maintained at a pressure of from about 0.5 Torr to about 20 Torr.

11. A method according to claim 1 further comprising cleaning the process chamber by:
(e) removing the substrate from the process zone of the process chamber; and
(f) providing an energized cleaning gas in the process zone, the energized cleaning gas comprising an oxygen-containing gas.

12. A method according to claim 11 wherein the oxygen-containing gas comprises nitrous oxide.

13. A low refractive index coating comprising:
(a) an amorphous structure containing carbon and fluorine;
(b) CF₂ bonds present in an atomic percentage of at least about 60%; and
(c) a refractive index of less than about 1.33.

14. A coating according to claim 13 comprising a ratio of fluorine to carbon of from about 1.8 to about 2.

15. A coating according to claim 13 comprising CF, CF₂, CF₃, and C—CF bonds.

16. A coating according to claim 13 that is formed by:
(i) placing a substrate in a process zone;
(ii) energizing in a remote zone, a deposition gas comprising a fluorocarbon gas and an additive gas; and
(iii) introducing the remotely energized deposition gas into the process zone to deposit the low refractive index coating on the substrate.

17. A coated photo-active device comprising:
(a) a photo-active feature; and
(b) a low refractive index coating overlying the photo-active feature, the coating having (i) an amorphous structure of carbon and fluorine, (ii) CF₂ bonds present in an atomic percentage of at least about 60%, and (iii) having a refractive index of less than about 1.33.

18. A CMOS image sensor comprising:
(a) a substrate;
(b) a photo-active feature on the substrate;
(c) at least one metal feature about the photo-active feature;
(d) a lens overlying the photo-active feature; and
(e) a low refractive index coating on the lens, the coating having (i) an amorphous structure of carbon and fluorine, (ii) CF₂ bonds present in an atomic percentage of at least about 60%, and (iii) having a refractive index of less than about 1.33.

19. A CMOS image sensor comprising:
(a) a substrate;
(b) an array of photo-active features on the substrate;
(c) twin stacks of metal features about each of the photo-active features;
(d) a color filter array comprising at least three different color filters disposed over the photo-active features;
(e) a plurality of lenses, each lens overlying a color filter; and
(f) a low refractive index coating on the lens, the coating having (i) an amorphous structure of carbon and fluorine, (ii) CF₂ bonds present in an atomic percentage of at least about 60%, and (iii) having a refractive index of less than about 1.33.

20. An image sensor according to claim 19 that is a front-illuminated CMOS image sensor or a back-illuminated CMOS image sensor.
